(19) United States
(12) Patent Application Publication
(10) Pub. No.: US 2015/0129514 A1
(43) Pub. Date: May 14, 2015

(54) RACK FOR COMPUTER SERVERS

(71) Applicant: NO RACK, Montreuil Cedex (FR)

(72) Inventors: Jeremie Bourdoncle, Lyon (FR); Julien Masanes, Montreuil (FR)

(21) Appl. No.: 14/395,135

(22) PCT Filed: Apr. 19, 2013
(86) PCT No.: PCT/FR2013/050866

§ 371 Date: Jan. 19, 2015

(30) Foreign Application Priority Data
Apr. 20, 2012 (FR) 12 53652

(51) Int. Cl. H05K 7/20

(52) U.S. Cl. CPC H05K 7/20709; H05K 7/20727
USPC 211/26

(57) ABSTRACT

The present invention concerns a rack for computer servers consisting of a carrier structure supporting a plurality of superposed trays extending substantially horizontally, each of said trays being fitted with electronic components organised so as to allow air to flow between the superposed trays and said electronic components, the air flow taking place between the ambient air, via an open area, and an inner discharge space extending perpendicular to said trays, said discharge space having a cylindrical configuration, said trays having the shape of superposed trapezoidal petals completely surrounding said cylindrically configured inner discharge space and said trays supporting radial separation means extending to a height of at least half the distance separating two superposed trays.

### BACKGROUND

1. Field of the Invention

The present invention relates to the field of data servers and supercomputers intended for mass storage, for example in data centres or “storage farms.”

Because of the density of electronic components (circuit cards, processors, and more particularly hard disks), these servers release a lot of heat, which requires an efficient heat discharge to enable the operation of the components at temperatures which do not affect the performances thereof.

Many solutions have been proposed to ensure heat discharge, by circulating water or even oil, and even using servers installed in polar regions (Greenland) or immersed.

The main problem arising in data centres is the cooling of servers that consumes as much (if not more) energy as the servers themselves. The operating cost of the servers depends on the depreciation of the equipment, but also on the consumption of power.

For example, a computer system operated by the University of Texas, fitted with 15,744 quad core microprocessors consumes 2.5 Megawatt, which results in power consumption the annual bill of which amounts to over a million dollars.

The field of the invention is more particularly that of energy-saving data servers, using a cooling system mainly operating by convective air circulation.

2. Solutions of the Prior Art

Various configurations have been proposed in the prior art in the form of cabinets (“rack”) containing cards organised in shelves and defining spaces so as to allow air coming from the outside of the cabinet and discharged into a chimney defined by the rear and side walls of the cabinet to flow. An upper discharge enables hot air to flow by convection and sometimes by forced ventilation.

The patent application PCT WO2008025745 describes a rack housing stackable modules for electronic equipment. Cooling is provided by natural convection through ventilation holes provided in the lower and upper walls thereof and by forced air cooling through internal air delivery rails supplied with pressurized air by means of a distribution box connected to a forced-air circulation line. Using internal delivery rails for forced air makes it possible for the circulation of drawn air to be only a slight obstacle to the air circulation obtained by natural convection.

The patent application PCT WO9713394 relates to an arrangement that may be used for cooling electronic equipment, where said electronic equipment is housed in a rack arrangement with means for transferring the heat energy produced by said electronic equipment to one or more rack-related cooling units. Each of such units is designed to transfer heat energy by means of convection to the ambient air about the rack and the equipment. At least one of said cooling units contains vertically-oriented cooling flanges, positioned next to one another, and a fan unit that is designed to be able to provide, on demand, the cooling unit and the cooling flanges with a stream of forced air. This arrangement thereby increases heat emission from the cooling flanges to the ambient air. The fan unit is located at the side of the rack unit, and positioned beside, or partly inside, the cooling unit. The fan unit is arranged to provide a stream of forced air to each space that is formed between the flanges of the cooling unit, with the flow of said stream of forced air being restricted to within the area for the sections of the cooling unit flanges that face the rack unit. The stream of air is produced for several collateral spaces and is aimed to flow in an upward direction.

The patent application US2009/0239460 discloses an assembly for extracting heat from a housing for the electronic equipment with an interior capacity that is adapted to hold heat generated by the electronic equipment, the housing having an essentially solid top portion and an essentially solid back portion.

The assembly includes a first opening in the top portion of the housing that leads to the housing interior, the first opening located at the back of the top portion, proximate the back portion of the housing, a second opening in the back portion of the housing that leads to the housing interior, the second opening located at the top of the back portion, proximate the top portion of the housing, wherein the first opening is contiguous with the second opening, and a chimney external to the housing and coupled to the housing such that the chimney encompasses and is in fluid communication with the first and second openings.

The American patent application US2011019362 describes an electronic equipment enclosure including a frame structure at least partially enclosed by a plurality of panels defining a compartment in which one or more electronic components are mounted. An exhaust air duct is adapted to exhaust hot air.

The American U.S. Pat. No. 4,158,875 discloses an air cooling equipment for use in electronic systems of the type having a plurality of printed circuit wiring boards with a plurality of heat-generating electronic components mounted thereon. The air cooling equipment uses a double-walled duct construction whereby air as a coolant is introduced in a direction at high angles to the wall.

3. Drawbacks of the Prior Art

The various solutions of the prior art are not satisfactory because they do not ensure an optimal floor use or an effective air flow to ensure uniform cooling of the electronic circuits, a significant reduction in the power consumption with respect to the prior solutions and improved power per surface area.

### SUMMARY

According to its most general sense, the present invention relates to a rack for computer servers comprising a carrier structure supporting a plurality of superposed trays extending substantially horizontally, each of said trays being fitted with electronic components organised so as to allow air to flow between the superposed trays and said electronic components, with the air flow taking place between the ambient air via an open area, and an inner discharge space extending perpendicularly to said trays. In order to remedy the above-mentioned objective problems, said carrier structure of the server rack according to the invention comprises modular blocks organised around a cavity forming a discharge space having a cylindrical configuration, and said trays have the shape of superposed trapezoidal petals completely surrounding said cylindrically configured inner discharge space. Said trays support radial separation means extending to a height of at least half the distance separating two superposed trays.

Some particular embodiments are disclosed below as alternative solutions.

In a first alternative solution, the separating means are constituted by at least a portion of at least the electronic components, with said components forming the separating means being substantially positioned radially to place the main faces in a substantially radial plane and perpendicular relative to the tray whereon they are mounted.

According to a second alternative solution not exclusive of the first one, said components forming the components separating means are hard disks.

According to another alternative solution not exclusive of the preceding two solutions, some of the separating means are constituted by passive partitions.

According to another alternative solution, the modular block comprises a lower base, uprights and an upper base, with the bases having a substantially trapezoidal shape.

In still another embodiment, the trays are removable and are supported by hoops fixed on the uprights.

Advantageously, the rear edges of the trays form deflector flaps.

According to a preferred embodiment, the server rack according to the invention has a hexagonal configuration, with six column-shaped modules opening on about 45 degrees.

According to another advantageous alternative solution, the rack according to the invention comprises forced air circulation means placed in the center duct.

### BRIEF DESCRIPTION OF THE DRAWINGS

The invention will be better understood when reading the following description, referring to the appended drawings corresponding to non-limiting exemplary embodiment wherein:

FIG. 1 shows a perspective view of a modular element (also called block or frame);

FIG. 2 shows a detailed view of a tray for the implementation of the invention;

FIG. 3 shows a perspective view of said modular element loaded with trays, and

FIG. 4 shows a perspective view in a cross-sectional plane of the rack according to the invention.

### DETAILED DESCRIPTION

The server rack according to the invention has a generally tubular shape, with frames forming modular blocks organised around a cavity shaped as a central column.

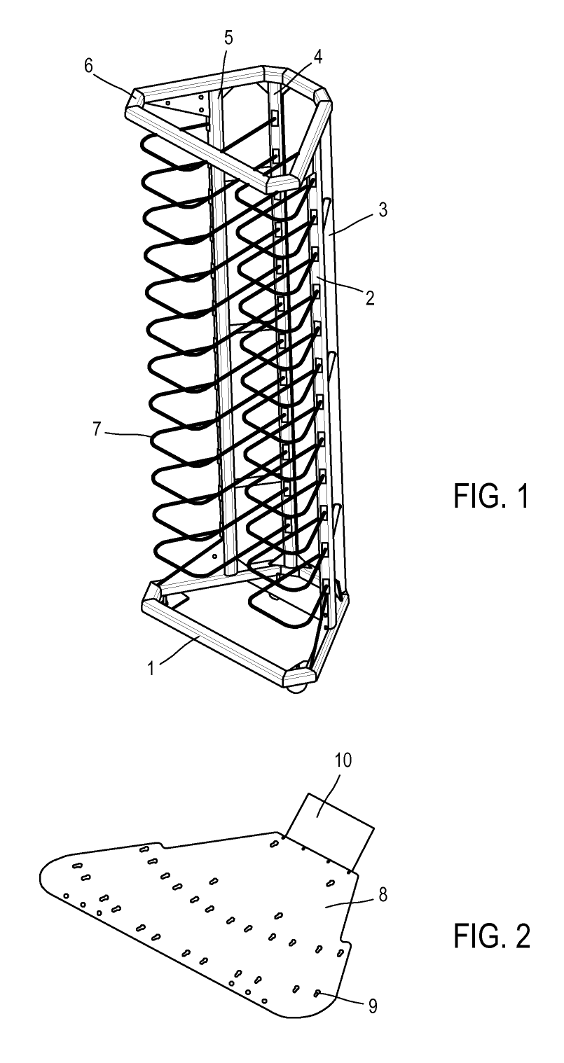

FIG. 1 shows a schematic view of a modular frame (or block) according to the invention. It consists of a lower base 1, uprights 2 to 5 and an upper base 6.

The bases 1, 6 have a substantially trapezoidal shape. They are formed with metal tubes having 40×40 mm square sections, with walls 2 millimetres thick.

The lower base 1 is mounted on a vibration-damping support and is provided with adjustable shim elements.

The uprights 2 to 5 also consist of metal tubes having 40×40 mm square sections, with walls 2 millimetres thick and a length of about 185 centimeters, in the described example.

These uprights 2 to 5 are so organised as to form a pair of right uprights and a pair of left uprights.

Each pair of uprights supports a series of metallic hoops 7 formed by bent rods regularly spaced apart for supporting the trays whereon the electronic components are mounted.

For this purpose, the uprights all have a series of equidistant perforations. All the uprights have the same perforations, which facilitates production and assembling.

FIG. 2 shows a perspective view of such a tray. It consists of a metal plate 8 bent and cut so to obtain the shape of a trapezoidal petal, opening on about 45 degrees. This metal plate is provided with a series of openings 9 for mounting accessories supported by the tray. The rear portion of the tray is provided with a deflector 10 directed upwards, when the tray is mounted on the modular block. This deflector 10 deviates the air flow produced by natural convection toward the top of the central column. It may be slightly twisted so as to create a central swirling air flow.

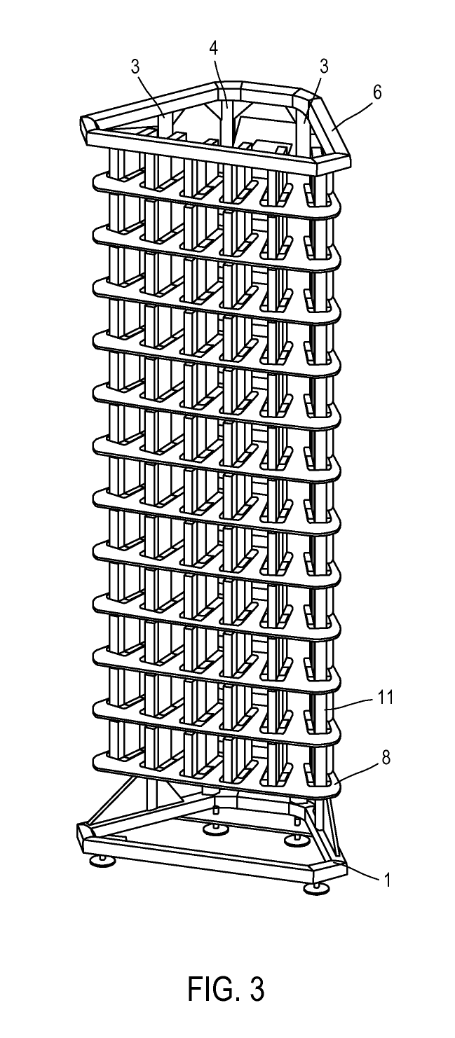

FIG. 3 shows a modular block with its trays and the electronic components.

The trays 8 are removable and are supported by the hoops fixed on the uprights 2 to 5. They are fitted with hard disks supports 11 enabling the rapid change through a front access.

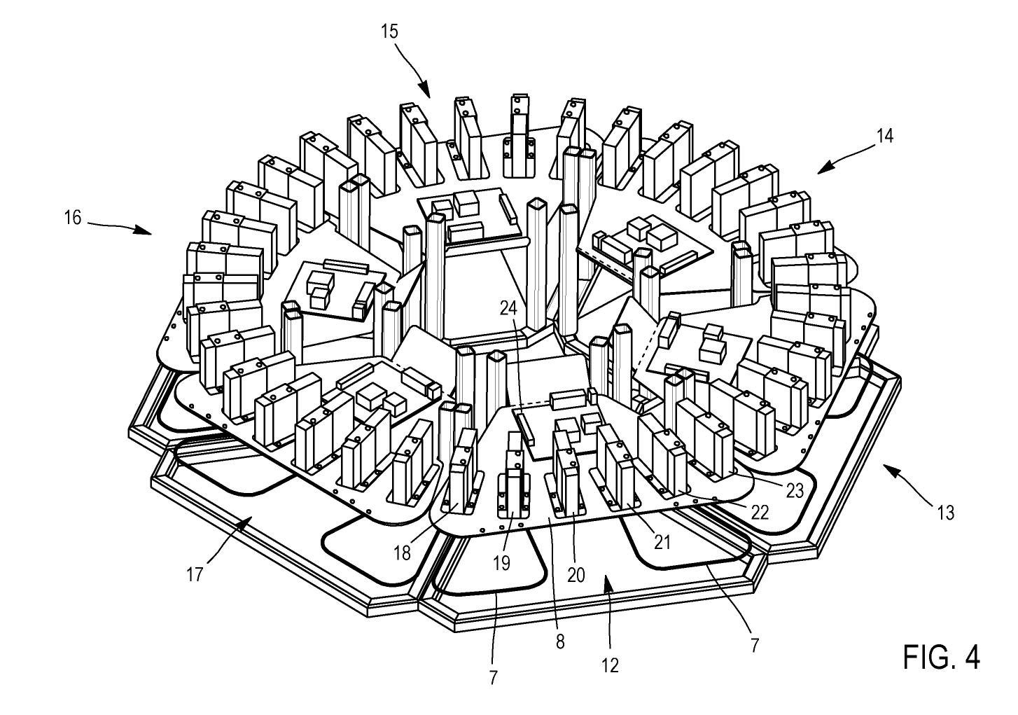

FIG. 4 shows a perspective view of the rack, in cross section.

It comprises six modular assemblies (or blocks) 12 to 17, each having a stack of trays 8 supported on either side by hoops 7.

Each tray 8 is provided with a series of radially oriented hard disks 18 to 23, with the main faces being vertically positioned to provide the largest possible surface area of contact with the air flowing through the rack and forming forced convection zones between two consecutive hard disks. Electronic cards 24 are mounted flat on the tray, with the heat being discharged by the passage of the air flowing through the spaces between the trays.

The central area forms a tubular chimney, wherein the air flowing by convection is discharged. Optionally, a forced air circulation system, e.g. a fan, is positioned within the column and/or at the outlet thereof.

1-9. (canceled)

10. A rack for computer servers comprising a carrier structure supporting a plurality of superposed trays extending substantially horizontally, each of said trays being fitted with electronic components organised so as to allow air to flow between the superposed trays and said electronic components, with the air flow taking place between the ambient air via an open area, and an inner discharge space extending perpendicularly to said trays, wherein the carrier structure comprises modular blocks organised around a cavity forming a discharge space having a cylindrical configuration, said trays having the shape of superposed trapezoidal petals completely surrounding said cylindrically configured inner discharge space and in that said trays support radial separation means extending to a height of at least half the distance separating the two superposed trays.

11. A rack for computer servers according to claim 10, wherein the radial separation means comprise at least a portion of at least the electronic components, with said components forming the radial separation means being substantially positioned radially to place the main faces in a substantially radial plane and perpendicular relative to the tray whereon they are mounted.

12. A rack for computer servers according to claim 11, wherein said components forming the radial separating means are hard disks.

13. A rack for computer servers according to claim 10, wherein some of the radial separating means are constituted by passive partitions.

14. A rack for computer servers according to claim 10, wherein the modular block comprises a lower base, uprights and an upper base, with the bases having a substantially trapezoidal shape.

15. A rack for computer servers according to the claim 14, wherein the trays are removable and are supported by hoops fixed on the uprights.

16. A rack for computer servers according to claim 10, wherein the rear edges of the trays form deflector flaps.

17. A rack for computer servers according to the claim 16, wherein said deflector flaps are twisted.

18. A rack for computer servers further comprising: a forced air circulation means placed in the center duct.
